(19) United States
(12) Patent Application Publication
(10) Pub. No.: US 2026/0136578 A1
(43) Pub. Date: May 14, 2026

(54) SEMICONDUCTOR DEVICE

(71) Applicant: KABUSHIKI KAISHA TOSHIBA, Tokyo (JP)

(72) Inventors: Aya SHINDOME, Yokohama (JP); Yosuke KAJIWARA, Yokohama (JP); Peitsen WU, Kawasaki (JP)

(73) Assignee: KABUSHIKI KAISHA TOSHIBA, Tokyo (JP)

(21) Appl. No.: 19/020,067

(22) Filed: Jan. 14, 2025

(30) Foreign Application Priority Data
May 10, 2024 (JP) 2024-077413

(51) Int. Cl. H10D 30/47; H10D 62/85; H10D 64/00

(52) U.S. Cl. CPC H10D 30/475; H10D 62/8503; H10D 64/112

(57) ABSTRACT

According to one embodiment, a semiconductor device includes first to third electrodes, a semiconductor member, first and second conductive members, and a first insulating member. The first conductive member is electrically connected to the first electrode. The second conductive member is electrically connected to the third electrode. The semiconductor member includes a first semiconductor region and a second semiconductor region. The first semiconductor region includes Alₓ₁Ga₁₋ₓ₁N (0≤x1<1). The second semiconductor region includes Alₓ₂Ga₁₋ₓ₂N (x1<x2≤1). The second semiconductor region includes a first semiconductor portion and a second semiconductor portion. The third electrode is between the semiconductor member and the second conductive member in the second direction. At least a part of the first insulating member is between the third partial region and the third electrode. The third electrode does not overlap the first insulating member in the first direction.

### CROSS-REFERENCE TO RELATED APPLICATIONS

This application is based upon and claims the benefit of priority from Japanese Patent Application No. 2024-077413, filed on May 10, 2024; the entire contents of which are incorporated herein by reference.

### FIELD

Embodiments described herein relate generally to a semiconductor device.

### BACKGROUND

For example, in semiconductor devices such as transistors, improvements in characteristics are desired.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to the first embodiment;

FIG. 4 is a schematic cross-sectional view illustrating a semiconductor device according to the first embodiment;

FIG. 5 is a schematic cross-sectional view illustrating a semiconductor device according to a second embodiment; and

FIG. 6 is a schematic cross-sectional view illustrating a semiconductor device according to the second embodiment.

### DETAILED DESCRIPTION

According to one embodiment, a semiconductor device includes a first electrode, a second electrode, a third electrode, a semiconductor member, a first conductive member, a second conductive member, and a first insulating member. The third electrode is provided between the first electrode and the second electrode in a first direction from the first electrode to the second electrode. The first conductive member is electrically connected to the first electrode. The second conductive member is electrically connected to the third electrode. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, and a fifth partial region. A second direction from the first partial region to the first electrode crosses the first direction. A direction from the second partial region to the second electrode is along the second direction. A direction from the third partial region to the third electrode is along the second direction. The fourth partial region is between the first partial region and the third partial region. The fifth partial region is between the third partial region and the second partial region. The second semiconductor region includes Alₓ₂Ga₁₋ₓ₂N (x1<x2≤1). The second semiconductor region includes a first semiconductor portion and a second semiconductor portion. A direction from the fourth partial region to the first semiconductor portion is along the second direction. A direction from the fifth partial region to the second semiconductor portion is along the second direction. The third electrode is between the semiconductor member and the second conductive member in the second direction. At least a part of the first insulating member is between the third partial region and the third electrode. The third electrode does not overlap the first insulating member in the first direction. The first conductive member includes a first conductive portion. A first conductive portion position of the first conductive portion in the first direction is between a second conductive member position of the second conductive member in the first direction and a second electrode position of the second electrode in the first direction. At least a part of the first conductive portion overlaps the second conductive member in the first direction. At least a part of the second conductive member overlaps the third electrode in the second direction. The first conductive portion includes a first portion and a second portion. The first portion overlaps the third electrode in the second direction. The second portion does not overlap the third electrode in the second direction. A first length of the first conductive portion along the first direction is longer than a second length of the third electrode along the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

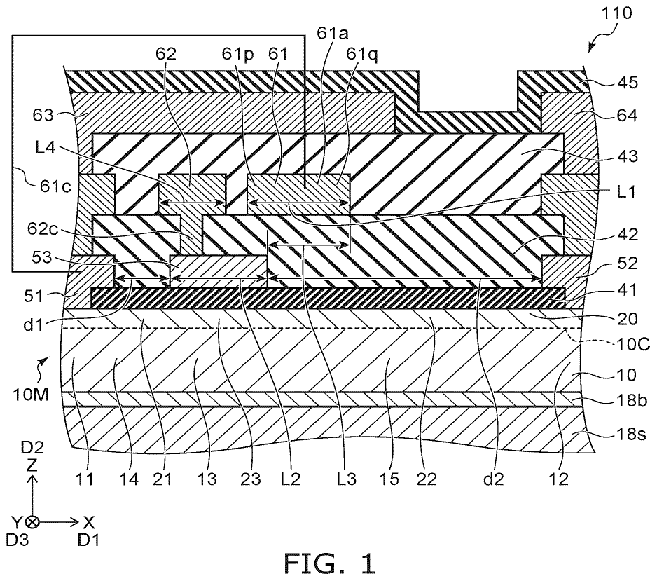

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a semiconductor member 10M, a first conductive member 61, and a second conductive member 62.

A first direction D1 from the first electrode 51 to the second electrode 52 is defined as an X-axis direction. One direction perpendicular to the X-axis direction is defined as a Z-axis direction. A direction perpendicular to the X-axis and Z-axis directions is defined as a Y-axis direction.

The third electrode 53 is provided between the first electrode 51 and the second electrode 52 in the first direction D1.

The first conductive member 61 is electrically connected to the first electrode 51. The second conductive member 62 is electrically connected to the third electrode 53.

The semiconductor member 10M includes a first semiconductor region 10 and a second semiconductor region 20. The first semiconductor region 10 includes Alₓ₁Ga₁₋ₓ₁N (0≤x1<1). The composition ratio x1 is, for example, not less than 0 and not more than 0.1. The first semiconductor region 10 may be, for example, a GaN layer.

The first semiconductor region 10 includes a first partial region 11, a second partial region 12, a third partial region 13, a fourth partial region 14, and a fifth partial region 15. A second direction D2 from the first partial region 11 to the first electrode 51 crosses the first direction D1. The second direction D2 is, for example, the Z-axis direction. The first electrode 51, the second electrode 52, and the third electrode 53 may extend along a third direction D3. The third direction D3 crosses a plane including the first direction D1 and the second direction D2. The third direction D3 may be, for example, the Y-axis direction.

A direction from the second partial region 12 to the second electrode 52 is along the second direction D2. A direction from the third partial region 13 to the third electrode 53 is along the second direction D2. The fourth partial region 14 is between the first partial region 11 and the third partial region 13. The fifth partial region 15 is between the third partial region 13 and the second partial region 12.

The second semiconductor region 20 includes Alₓ₂Ga₁₋ₓ₂N (x1<x2≤1). The composition ratio x2 is, for example, not less than 0.1 and not more than 0.5. The second semiconductor region 20 may be, for example, an AlGaN layer.

The second semiconductor region 20 includes a first semiconductor portion 21 and a second semiconductor portion 22. A direction from the fourth partial region 14 to the first semiconductor portion 21 is along the second direction D2. A direction from the fifth partial region 15 to the second semiconductor portion 22 is along the second direction D2. In this example, the second semiconductor region 20 further includes a third semiconductor portion 23. The third semiconductor portion 23 is between the third partial region 13 and the third electrode 53 in the second direction D2.

The third electrode 53 is between the semiconductor member 10M and the second conductive member 62 in the second direction D2. The first conductive member 61 includes a first conductive portion 61a. A position (first conductive portion position) of the first conductive portion 61a in the first direction D1 is between a position (second conductive member position) of the second conductive member 62 in the first direction D1 and a position (second electrode position) of the second electrode 52 in the first direction D1.

At least a part of the first conductive portion 61a overlaps the second conductive member 62 in the first direction D1. For example, a direction from the second conductive member 62 to the first conductive portion 61a is along the first direction D1. The first conductive portion 61a is separated from the second conductive member 62 in the first direction D1. A gap is provided between the first conductive portion 61a and the second conductive member 62.

At least a part of the second conductive member 62 overlaps the third electrode 53 in the second direction D2. The first conductive portion 61a includes a first portion 61p and a second portion 61q. The first portion 61p overlaps the third electrode 53 in the second direction D2. The second portion 61q does not overlap the third electrode 53 in the second direction D2. The gap between the first conductive portion 61a and the second conductive member 62 overlaps the third electrode 53 in the second direction D2.

A length of the first conductive portion 61a along the first direction D1 is defined as a first length L1. A length of the third electrode 53 along the first direction D1 is defined as the second length L2. In the embodiment, the first length L1 is longer than the second length L2. By this configuration, a semiconductor device with improved characteristics can be provided.

A current flowing between the first electrode 51 and the second electrode 52 can be controlled by a potential of the third electrode 53. For example, the potential of the third electrode 53 may be a potential based on a potential of the first electrode 51. For example, the first electrode 51 is one of the source electrode and the drain electrode. The second electrode 52 is the other of the source electrode and the drain electrode. The third electrode 53 is a gate electrode. The semiconductor device 110 is, for example, a transistor.

The first semiconductor region 10 includes a portion facing the second semiconductor region 20. A carrier region 10C is formed in this portion. The carrier region 10C is, for example, a two-dimensional electron gas. The semiconductor device is, for example, a HEMT (High Electron Mobility Transistor).

For example, a distance along the first direction D1 between the first electrode 51 and the third electrode 53 is defined as a first distance d1. A distance along the first direction D1 between the third electrode 53 and the second electrode 52 is defined as a second distance d2. For example, the first distance d1 is shorter than the second distance d2. In this case, the first electrode 51 is a source electrode, and the second electrode 52 is the drain electrode.

In the embodiment, the second conductive member 62 functions, for example, as a gate field plate. The first conductive member 61 functions, for example, as a source field plate. Thereby, the electric field is reduced. A high breakdown voltage is obtained.

For example, in a first reference example, the second conductive member 62 is provided, and the first conductive member 61 is not provided. In such a first reference example, a low gate resistance is obtained. However, in the first reference example, the gate-drain capacitance Cgd increases. This results in, for example, large losses.

For example, in a second reference example, the first conductive member 61 is provided, and the second conductive member 62 is not provided. In such a second reference example, a small gate-drain capacitance Cgd is obtained. However, in the second reference example, it is difficult to obtain a low gate resistance.

In a third reference example, the first conductive member 61 and the second conductive member 62 are provided. Thereby, a low gate resistance and a small gate-drain capacitance Cgd can be obtained. In the third reference example, the gap between the first conductive member 61 and the second conductive member 62 does not overlap the third electrode 53. In the third reference example, this gap is located between the third electrode 53 and the second electrode 52. In the third reference example, when a high voltage is applied to the second electrode 52, the electric field in the gap becomes strong. This is because the gap does not overlap the third electrode 53, making it difficult for the depletion layer to spread in the gap. For example, operation becomes unstable. For example, breakdown is more likely to occur.

In contrast, in the embodiment, a first conductive member 61 and a second conductive member 62 are provided. This provides a low gate resistance and a small gate-drain capacitance Cgd. Furthermore, the gap between the first conductive member 61 (first conductive portion 61a) and the second conductive member 62 overlaps the third electrode 53 in the second direction D2. Thereby, the electric field in the gap when a high voltage is applied to the second electrode 52 can be relaxed. For example, stable operation is easily obtained. For example, breakdown is suppressed. According to the embodiment, a semiconductor device capable of improving characteristics can be provided.

As already explained, in the embodiment, the first length L1 is longer than the second length L2. Thereby, the first conductive portion 61a of the first conductive member 61 can protrude a sufficiently long distance toward the second electrode 52, with the third electrode 53 as the reference. Thereby, the electric field can be relaxed more effectively. More stable characteristics are obtained.

For example, a length of the second portion 61q of the first conductive portion 61a of the first conductive member 61 along the first direction D1 is defined as a third length L3. The third length L3 may be, for example, 0.05 times or more the second distance d2. The electric field is more effectively relaxed. The third length L3 may be, for example, 0.7 times or less the second distance d2.

As shown in FIG. 1, the semiconductor device 110 may further include a second conductive member connecting portion 62c. The second conductive member connecting portion 62c is provided between the third electrode 53 and the second conductive member 62 in the second direction D2. The second conductive member connecting portion 62c electrically connects the second conductive member 62 to the third electrode 53.

A length of the second conductive member 62 in the first direction D1 is defined as a fourth length L4. A width of the second conductive member connecting portion 62c in the second direction D2 is shorter than the second length L2 and shorter than the fourth length L4. The second conductive member connecting portion 62c is, for example, a via conductive member.

As shown in FIG. 1, the semiconductor device 110 may further include a first conductive member connecting portion 61c. The first conductive member connecting portion 61c electrically connects the first conductive member 61 to the first electrode 51. For example, the first conductive member connecting portion 61c may electrically connect the first conductive member 61 to the first electrode 51 in a cross section different from the cross section illustrated in FIG. 1.

As shown in FIG. 1, the semiconductor member 10M may include a base 18s and a nitride layer 18b. The nitride layer 18b is provided between the base 18s and the second semiconductor region 20. The first semiconductor region 10 is provided between the nitride layer 18b and the second semiconductor region 20. The base 18s may include, for example, a silicon substrate. The nitride layer 18b may include Al, Ga, and N. The nitride layer 18b is, for example, a buffer layer.

The semiconductor device 110 may further include a first insulating member 41. At least a part of the first insulating member 41 is provided between the semiconductor member 10M and the third electrode 53. At least a part of the first insulating member 41 may function as a gate insulating film.

In the semiconductor device 110, at least a part of the first insulating member 41 is provided between the third partial region 13 and the third electrode 53. At least a part of the first insulating member 41 is provided between the third semiconductor portion 23 and the third electrode 53. The third electrode 53 does not overlap the first insulating member 41 in the first direction D1.

A part of the first insulating member 41 may be provided between the semiconductor member 10M and a part of the second electrode 52. Another part of the first insulating member 41 may be provided between the semiconductor member 10M and another part of the first electrode 51.

The semiconductor device 110 may further include a second insulating member 42. At least a part of the second insulating member 42 is provided between the third electrode 53 and the first conductive member 61 (e.g., the first conductive portion 61a).

The semiconductor device 110 may further include a third insulating member 43. At least a part of the third insulating member 43 is provided between the second conductive member 62 and the first conductive portion 61a in the first direction D1.

For example, between the first conductive member 61 and the second electrode 52, there is no other conductive member that is electrically connected to the first electrode 51 and separated from the first conductive member 61.

The semiconductor device 110 may further include a third conductive member 63 electrically connected to the first electrode 51. In this example, the first conductive member 61 is provided between the semiconductor member 10M and at least a part of the third conductive member 63 in the second direction D2.

The semiconductor device 110 may further include a fourth conductive member 64 electrically connected to the second electrode 52. The second electrode 52 is provided between the semiconductor member 10M and the fourth conductive member 64 in the second direction D2.

The semiconductor device 110 may further include a fifth insulating member 45. The third conductive member 63 is provided between the third insulating member 43 and the fifth insulating member 45 in the second direction D2.

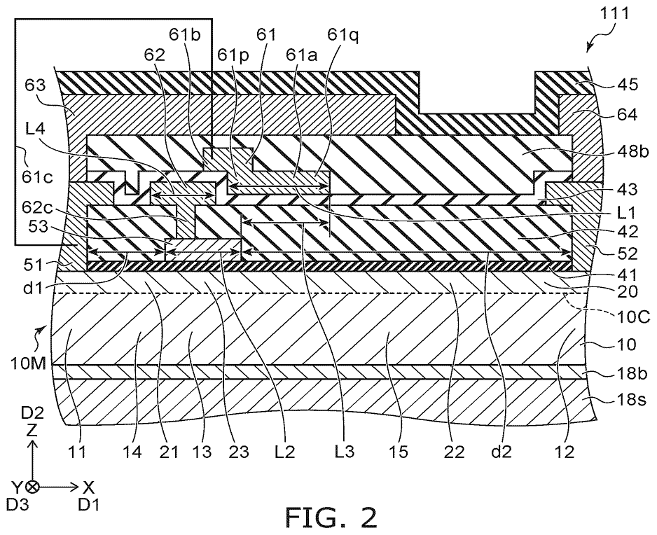

FIG. 2 is a schematic cross-sectional view illustrating a semiconductor device according to the first embodiment.

As shown in FIG. 2, in a semiconductor device 111 according to the embodiment, the shape of the first conductive member 61 is different from that in the semiconductor device 110. Except for this, the configuration of the semiconductor device 111 may be similar to the configuration of the semiconductor device 110.

In the semiconductor device 111, the first conductive member 61 further includes a second conductive portion 61b. The second conductive portion 61b is continuous with the first conductive portion 61a. At least a part of the second conductive member 62 is provided between the third electrode 53 and the second conductive portion 61b in the second direction D2. The resistance of the first conductive member 61 can be reduced.

At least a part of the third insulating member 43 is provided between the second conductive member 62 and the first conductive portion 61a in the first direction D1. Another part of the third insulating member 43 is provided between the second conductive member 62 and the second conductive portion 61b in the second direction D2.

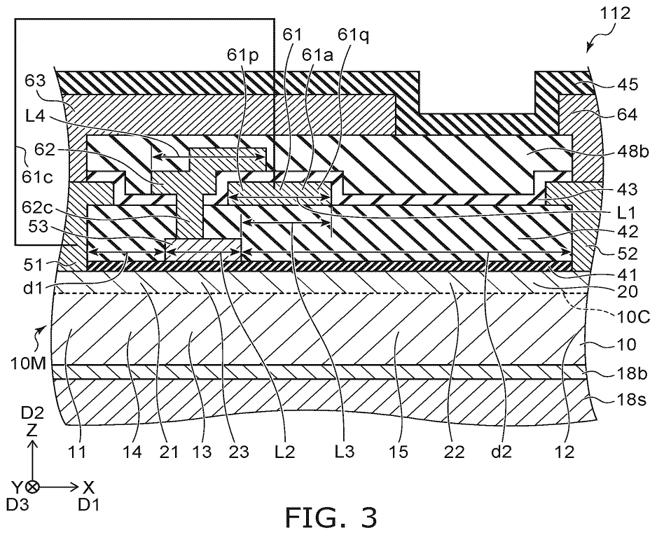

FIG. 3 is a schematic cross-sectional view illustrating a semiconductor device according to the first embodiment.

As shown in FIG. 3, in a semiconductor device 112 according to the embodiment, the shape of the second conductive member 62 is different from that in the semiconductor device 110. Except for this, the configuration of the semiconductor device 112 may be similar to the configuration of the semiconductor device 110.

In the semiconductor device 112, the first portion 61p is provided between the third electrode 53 and a part of the second conductive member 62 in the second direction D2. The resistance of the second conductive member 62 can be reduced.

A part of the third insulating member 43 is provided between the first portion 61p and a part of the second conductive member 62 in the second direction D2.

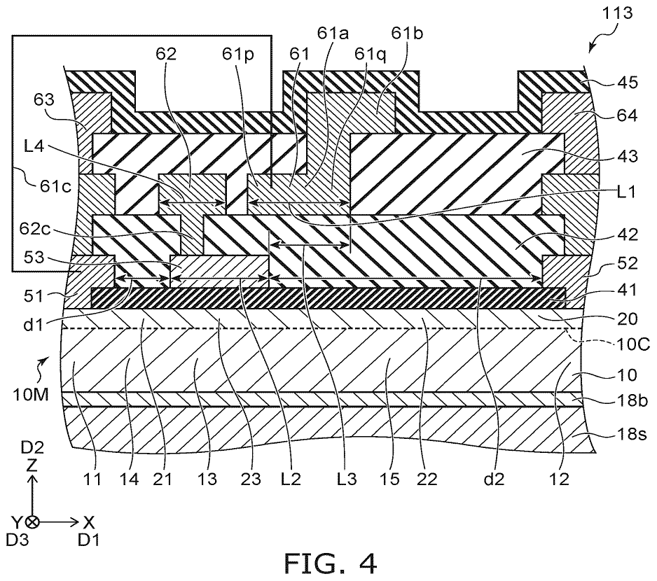

FIG. 4 is a schematic cross-sectional view illustrating a semiconductor device according to the first embodiment.

As shown in FIG. 4, in a semiconductor device 113 according to the embodiment, the configuration of the first conductive member 61 differs from that in the semiconductor device 110 and the like. Except for this, the configuration of the semiconductor device 113 may be similar to the configuration of the semiconductor device 110 and the like.

In the semiconductor device 113, the first conductive member 61 further includes the second conductive portion 61b. The second conductive portion 61b is continuous with the first conductive portion 61a. A position of the second conductive portion 61b in the first direction D1 (second conductive portion position) is between a position of the first portion 61p in the first direction D1 (first portion position) and the position of the second electrode 52 in the first direction D1 (second electrode position). At least a part of the second portion 61q is provided between the semiconductor member 10M and the second conductive portion 61b in the second direction D2. In the semiconductor device 113, the electric field can be suppressed more effectively.

### Second Embodiment

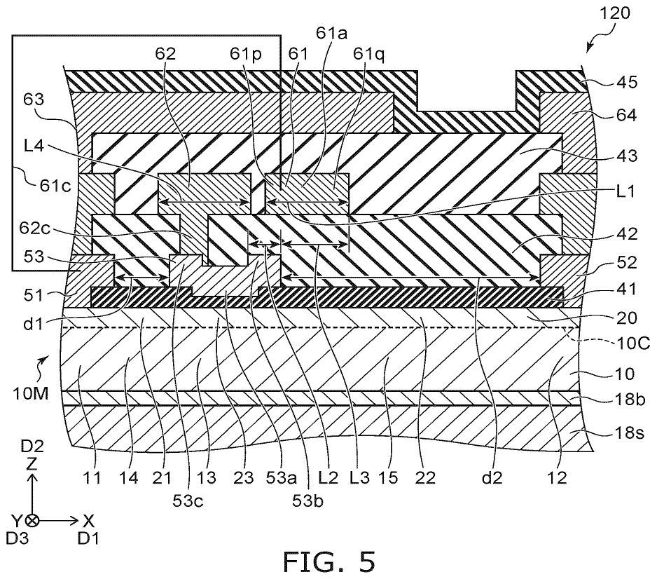

FIG. 5 is a schematic cross-sectional view illustrating a semiconductor device according to a second embodiment.

As shown in FIG. 5, in a semiconductor device 120 according to the embodiment, the shape of the third electrode 53 is different from that in the semiconductor device 110. Except for this, the configuration of the semiconductor device 120 may be similar to that of the semiconductor device 110, etc. The configuration described in relation to the first embodiment may be applied to the semiconductor device 120.

The semiconductor device 120 includes the first electrode 51, the second electrode 52, the third electrode 53, the semiconductor member 10M, the first conductive member 61, the second conductive member 62, and the first insulating member 41. The third electrode 53 is provided between the first electrode 51 and the second electrode 52 in the first direction D1 from the first electrode 51 to the second electrode 52. The third electrode 53 includes a first electrode portion 53a and a second electrode portion 53b. The second electrode portion 53b is connected to the first electrode portion 53a.

The first conductive member 61 is electrically connected to the first electrode 51. The second conductive member 62 is electrically connected to the third electrode 53.

The semiconductor member 10M includes the first semiconductor region 10 and ta second semiconductor region 20. The first semiconductor region 10 includes Alₓ₁Ga₁₋ₓ₁N (0≤x1<1). The first semiconductor region 10 includes the first partial region 11, the second partial region 12, the third partial region 13, the fourth partial region 14, and the fifth partial region 15. The second direction D2 from the first partial region 11 to the first electrode 51 crosses the first direction D1. The direction from the second partial region 12 to the second electrode 52 is along the second direction D2. The direction from the third partial region 13 to the third electrode 53 is along the second direction D2. The fourth partial region 14 is between the first partial region 11 and the third partial region 13. The fifth partial region 15 is between the third partial region 13 and the second partial region 12.

The second semiconductor region 20 includes Alₓ₂Ga₁₋ₓ₂N (x1<x2≤1). The second semiconductor region 20 includes the first semiconductor portion 21 and the second semiconductor portion 22. The direction from the fourth partial region 14 to the first semiconductor portion 21 is along the second direction D2. The direction from the fifth partial region 15 to the second semiconductor portion 22 is along the second direction D2.

The third electrode 53 is provided between the semiconductor member 10M and the second conductive member 62 in the second direction D2. At least a part of the first insulating member 41 is provided between the third partial region 13 and the third electrode 53. At least a part of the first electrode portion 53a is provided between a part of the first insulating member 41 and another part of the first insulating member 41 in the first direction D1. A position (second electrode portion position) of the second electrode portion 53b in the first direction D1 is between a position (first electrode portion position) of the first electrode portion 53a in the first direction D1 and the position (second electrode position) of the second electrode 52 in the first direction D1. The second electrode portion 53b does not overlap the first insulating member 41 in the first direction D1.

The first electrode portion 53a is provided in a recess in the first insulating member 41. The second electrode portion 53b corresponds to the “eaves portion” on the first insulating member 41.

The third electrode 53 may include a third electrode portion 53c. The third electrode portion 53c is connected to the first electrode portion 53a. A position (third electrode portion position) of the third electrode portion 53c in the first direction D1 is between a position (first electrode position) of the first electrode 51 in the first direction D1 and a position (first electrode portion position) of the first electrode portion 53a in the first direction D1. The third electrode portion 53c does not overlap the first insulating member 41 in the first direction D1. The third electrode portion 53c corresponds to the “eaves portion” on the first insulating member 41.

The first distance d1 along the first direction D1 between the first electrode 51 and the third electrode 53 is shorter than the second distance d2 along the first direction D1 between the third electrode 53 and the second electrode 52.

The first conductive member 61 includes a first conductive portion 61a. The position (first conductive portion position) of the first conductive portion 61a in the first direction D1 is between the position (second conductive member position) of the second conductive member 62 in the first direction D1 and the position (second electrode position) of the second electrode 52 in the first direction D1.

At least a part of the first conductive portion 61a overlaps the second conductive member 62 in the first direction D1. At least a part of the second conductive member 62 overlaps the third electrode 53 in the second direction D2. The first conductive portion 61a includes the first portion 61p and the second portion 61q. The first portion 61p overlaps the second electrode portion 53b in the second direction D2. The second portion 61q does not overlap the third electrode 53 in the second direction D2. The gap between the first conductive member 61 (first conductive portion 61a) and the second conductive member 62 overlaps the third electrode 53 in the second direction D2.

The length of the first conductive portion 61a along the first direction D1 is defined as the first length L1. In the second embodiment, the length of the second electrode portion 53b (eaves portion) along the first direction D1 is defined as the second length L2. In the second embodiment, the first length L1 is longer than the second length L2.

By providing the first conductive member 61 and the second conductive member 62, a low gate resistance and a small gate-drain capacitance Cgd are obtained. Furthermore, the gap between the first conductive member 61 (first conductive portion 61a) and the second conductive member 62 overlaps the third electrode 53 in the second direction D2. Thereby, the electric field in the gap when a high voltage is applied to the second electrode 52 can be effectively relaxed. By the first length L1 being longer than the second length L2, the first conductive portion 61a of the first conductive member 61 can protrude a sufficiently long distance toward the second electrode 52 with respect to the second electrode portion 53b. Thereby, the electric field is more effectively relaxed. More stable characteristics are obtained.

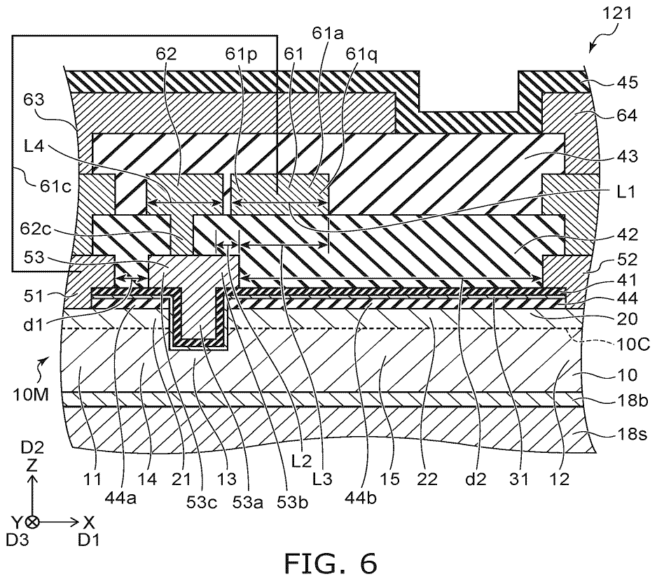

FIG. 6 is a schematic cross-sectional view illustrating a semiconductor device according to the second embodiment.

As shown in FIG. 6, in a semiconductor device 121 according to the embodiment, the configuration of the third electrode 53 is different from that in the semiconductor device 120. Except for this, the configuration of the semiconductor device 121 may be similar to the configuration of the semiconductor device 120.

In the semiconductor device 121, the first electrode portion 53a is provided between the first semiconductor portion 21 and the second semiconductor portion 22 in the first direction D1. In this example, a part of the first electrode portion 53a is provided between the fourth partial region 14 and the fifth partial region 15 in the first direction D1. The third electrode 53 is, for example, a recessed gate electrode. For example, a high threshold voltage is obtained. For example, normally-off operation is obtained.

In the semiconductor device 121, the length of the first conductive portion 61a along the first direction D1 is defined as the first length L1. The length of the second electrode portion 53b (eaves portion) along the first direction D1 is defined as the second length L2. In the semiconductor device 120, the first length L1 is longer than the second length L2. The electric field is relaxed more effectively. More stable characteristics are obtained.

The semiconductor device 121 may include the first insulating member 41. At least a part of the first insulating member 41 is provided between the first semiconductor portion 21 and the third electrode 53, between the third electrode 53 and the second semiconductor portion 22, and between the third partial region 13 and the third electrode 53.

The semiconductor device 121 may include a first compound member 31. The first compound member 31 includes Al_{z1}Ga_{1-z1}N (0<z1≤1). The composition ratio z1 is, for example, not less than 0.85 and not more than 1. The first compound member 31 may be, for example, an AlN layer. The first compound member 31 is provided between the semiconductor member 10M and the first insulating member 41. By providing the first compound member 31, for example, a low on-resistance is obtained.

The semiconductor device 121 may further include the fourth insulating member 44. The fourth insulating member 44 includes a first insulating region 44a and a second insulating region 44b. The first semiconductor portion 21 is provided between the fourth partial region 14 and the first insulating region 44a in the second direction D2. The second semiconductor portion 22 is provided between the fifth partial region 15 and the second insulating region 44b in the second direction D2. The second semiconductor region 20 is protected by the fourth insulating member 44.

In the embodiment, information regarding the shape of the semiconductor region can be obtained, for example, by electron microscope observation. Information regarding the composition and element concentration in the semiconductor region can be obtained, for example, by EDX (Energy Dispersive X-ray Spectroscopy) or SIMS (Secondary Ion Mass Spectrometry). Information regarding the composition in the semiconductor region can be obtained, for example, by reciprocal space mapping.

The embodiments may include the following Technical proposals:

### Technical Proposal 1

A semiconductor device, comprising:
a first electrode;
a second electrode;
a third electrode provided between the first electrode and the second electrode in a first direction from the first electrode to the second electrode;
a semiconductor member;
a first conductive member electrically connected to the first electrode;
a second conductive member electrically connected to the third electrode; and
a first insulating member,
the semiconductor member including a first semiconductor region and a second semiconductor region,
the first semiconductor region including Alₓ₁Ga₁₋ₓ₁N (0≤x1<1),
the first semiconductor region including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the third electrode being along the second direction,
the fourth partial region being between the first partial region and the third partial region,
the fifth partial region being between the third partial region and the second partial region,
the second semiconductor region including Alₓ₂Ga₁₋ₓ₂N (x1<x2≤1),
the second semiconductor region including a first semiconductor portion and a second semiconductor portion,
a direction from the fourth partial region to the first semiconductor portion being along the second direction,
a direction from the fifth partial region to the second semiconductor portion being along the second direction,
the third electrode being between the semiconductor member and the second conductive member in the second direction,
at least a part of the first insulating member being between the third partial region and the third electrode,
the third electrode not overlapping the first insulating member in the first direction,
the first conductive member including a first conductive portion,
a first conductive portion position of the first conductive portion in the first direction being between a second conductive member position of the second conductive member in the first direction and a second electrode position of the second electrode in the first direction,
at least a part of the first conductive portion overlapping the second conductive member in the first direction,
at least a part of the second conductive member overlapping the third electrode in the second direction,
the first conductive portion including a first portion and a second portion,
the first portion overlapping the third electrode in the second direction,
the second portion not overlapping the third electrode in the second direction, and
a first length of the first conductive portion along the first direction being longer than a second length of the third electrode along the first direction.

### Technical Proposal 2

A semiconductor device, comprising:
a first electrode;
a second electrode;
a third electrode provided between the first electrode and the second electrode in a first direction from the first electrode to the second electrode, the third electrode including a first electrode portion and a second electrode portion connected to the first electrode portion;
a semiconductor member;
a first conductive member electrically connected to the first electrode;
a second conductive member electrically connected to the third electrode; and
a first insulating member,
the semiconductor member including a first semiconductor region and a second semiconductor region,
the first semiconductor region including Alₓ₁Ga₁₋ₓ₁N (0≤x1<1),
the first semiconductor region including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the third electrode being along the second direction,
the fourth partial region being between the first partial region and the third partial region,
the fifth partial region being between the third partial region and the second partial region,
the second semiconductor region including Alₓ₂Ga₁₋ₓ₂N (x1<x2≤1),
the second semiconductor region including a first semiconductor portion and a second semiconductor portion,
a direction from the fourth partial region to the first semiconductor portion being along the second direction,
a direction from the fifth partial region to the second semiconductor portion being along the second direction,
the third electrode being between the semiconductor member and the second conductive member in the second direction,
at least a part of the first insulating member being between the third partial region and the third electrode,
at least a part of the first electrode portion being between a part of the first insulating member and another part of the first insulating member in the first direction,
a second electrode portion position of the second electrode portion in the first direction being between a first electrode portion position of the first electrode portion in the first direction and a second electrode portion position of the second electrode in the first direction,
the second electrode portion not overlapping the first insulating member in the first direction,
the first conductive member includes a first conductive portion,
a first conductive portion position of the first conductive portion in the first direction being between a second conductive member position of the second conductive member in the first direction and the second electrode position,
at least a part of the first conductive portion overlapping the second conductive member in the first direction,
at least a part of the second conductive member overlapping the third electrode in the second direction,
the first conductive portion including a first portion and a second portion,
the first portion overlapping the second electrode portion in the second direction,
the second portion not overlapping the third electrode portion in the second direction,
a first length of the first conductive portion along the first direction being longer than a second length of the second electrode portion along the first direction.

### Technical Proposal 3

The semiconductor device according to Technical proposal 2, wherein
at least a part of the first electrode portion is provided between the first semiconductor portion and the second semiconductor portion in the first direction.

### Technical Proposal 4

The semiconductor device according to Technical proposal 2 or 3, wherein
a part of the first electrode portion is provided between the fourth partial region and the fifth partial region in the first direction.

### Technical Proposal 5

The semiconductor device according to Technical proposal 4, further comprising:
a first compound member including Al_{z1}Ga_{1-z1}N (0<z1≤1),
the first compound member being provided between the semiconductor member and the first insulating member.

### Technical Proposal 6

The semiconductor device according to any one of Technical proposals 2-5, further comprising:
a fourth insulating member,
the fourth insulating member including a first insulating region and a second insulating region,
the first semiconductor portion being between the fourth partial region and the first insulating region in the second direction, and
the second semiconductor portion being between the fifth partial region and the second insulating region in the second direction.

### Technical Proposal 7

The semiconductor device according to any one of Technical proposals 1-6, wherein
The first conductive portion is spaced from the second conductive member in the first direction.

### Technical Proposal 8

The semiconductor device according to any one of Technical proposals 1-7, wherein
a first distance along the first direction between the first electrode and the third electrode is shorter than a second distance along the first direction between the third electrode and the second electrode.

### Technical Proposal 9

The semiconductor device according to Technical proposal 8, wherein
a third length of the second portion along the first direction is not less than 0.05 times and not more than 0.7 times the second distance.

### Technical Proposal 10

The semiconductor device according to any one of Technical proposals 1-9, further comprising:
a second conductive member connecting portion,
the second conductive member connecting portion is between the third electrode and the second conductive member in the second direction,
the second conductive member connecting portion electrically connects the second conductive member to the third electrode, and
a width of the second conductive member connecting portion in the first direction is shorter than the second length and shorter than a fourth length of the second conductive member in the first direction.

### Technical Proposal 11

The semiconductor device according to any one of Technical proposals 1-10, further comprising:
a first conductive member connecting portion,
the first conductive member connecting portion electrically connects the first conductive member to the first electrode.

### Technical Proposal 12

The semiconductor device according to any one of Technical proposals 1-11, wherein
the first conductive member further includes a second conductive portion,
the second conductive portion is continuous with the first conductive portion, and
at least a part of the second conductive member is between the third electrode and the second conductive portion in the second direction.

### Technical Proposal 13

The semiconductor device according to any one of Technical proposals 1-11, wherein
the first conductive member further includes a second conductive portion,
the second conductive portion is continuous with the first conductive portion,
a second conductive portion position of the second conductive portion in the first direction is between a first portion position of the first portion in the first direction and the second electrode position, and
at least a part of the second portion is between the semiconductor member and the second conductive portion in the second direction.

### Technical Proposal 14

The semiconductor device according to any one of Technical proposals 1-11, wherein
the first portion is provided between the third electrode and a part of the second conductive member in the second direction.

### Technical Proposal 15

The semiconductor device according to any one of Technical proposals 1-14, wherein
the second semiconductor region further includes a third semiconductor portion, and
the third semiconductor portion is between the third partial region and the third electrode in the second direction.

### Technical Proposal 16

The semiconductor device according to any one of Technical proposals 1-15, wherein
a part of the first insulating member is provided between the semiconductor member and a part of the second electrode.

### Technical Proposal 17

The semiconductor device according to any one of Technical proposals 1-16, further comprising:
a second insulating member, and
at least a part of the second insulating member being provided between the third electrode and the first conductive portion.

### Technical Proposal 18

The semiconductor device according to any one of Technical proposals 1-17, further comprising:
a third insulating member, and
at least a part of the third insulating member being provided between the second conductive member and the first conductive portion in the first direction.

### Technical Proposal 19

The semiconductor device according to any one of Technical proposals 1-18, wherein
no other conductive member electrically connected to the first electrode and separated from the first conductive member is provided between the first conductive member and the second electrode.

### Technical Proposal 20

The semiconductor device according to any one of Technical proposals 1-19, further comprising:
a third conductive member electrically connected to the first electrode, and
the first conductive member is provided between the semiconductor member and at least a part of the third conductive member in the second direction.

According to the embodiment, a semiconductor device whose characteristics can be improved is provided.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrode, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode provided between the first electrode and the second electrode in a first direction from the first electrode to the second electrode;
a semiconductor member;
a first conductive member electrically connected to the first electrode;
a second conductive member electrically connected to the third electrode; and
a first insulating member,
the semiconductor member including a first semiconductor region and a second semiconductor region,
the first semiconductor region including Alₓ₁Ga₁₋ₓ₁N (0≤x1<1),
the first semiconductor region including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the third electrode being along the second direction,
the fourth partial region being between the first partial region and the third partial region,
the fifth partial region being between the third partial region and the second partial region,
the second semiconductor region including Alₓ₂Ga₁₋ₓ₂N (x1<x2≤1),
the second semiconductor region including a first semiconductor portion and a second semiconductor portion,
a direction from the fourth partial region to the first semiconductor portion being along the second direction,
a direction from the fifth partial region to the second semiconductor portion being along the second direction,
the third electrode being between the semiconductor member and the second conductive member in the second direction,
at least a part of the first insulating member being between the third partial region and the third electrode,
the third electrode not overlapping the first insulating member in the first direction,
the first conductive member including a first conductive portion,
a first conductive portion position of the first conductive portion in the first direction being between a second conductive member position of the second conductive member in the first direction and a second electrode position of the second electrode in the first direction,
at least a part of the first conductive portion overlapping the second conductive member in the first direction,
at least a part of the second conductive member overlapping the third electrode in the second direction,
the first conductive portion including a first portion and a second portion,
the first portion overlapping the third electrode in the second direction,
the second portion not overlapping the third electrode in the second direction, and
a first length of the first conductive portion along the first direction being longer than a second length of the third electrode along the first direction.

2. A semiconductor device, comprising:
a first electrode;
a second electrode;
a third electrode provided between the first electrode and the second electrode in a first direction from the first electrode to the second electrode, the third electrode including a first electrode portion and a second electrode portion connected to the first electrode portion;
a semiconductor member;
a first conductive member electrically connected to the first electrode;
a second conductive member electrically connected to the third electrode; and
a first insulating member,
the semiconductor member including a first semiconductor region and a second semiconductor region,
the first semiconductor region including Alₓ₁Ga₁₋ₓ₁N (0≤x1<1),
the first semiconductor region including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the third electrode being along the second direction,
the fourth partial region being between the first partial region and the third partial region,
the fifth partial region being between the third partial region and the second partial region,
the second semiconductor region including Alₓ₂Ga₁₋ₓ₂N (x1<x2≤1),
the second semiconductor region including a first semiconductor portion and a second semiconductor portion,
a direction from the fourth partial region to the first semiconductor portion being along the second direction,
a direction from the fifth partial region to the second semiconductor portion being along the second direction,
the third electrode being between the semiconductor member and the second conductive member in the second direction,
at least a part of the first insulating member being between the third partial region and the third electrode,
at least a part of the first electrode portion being between a part of the first insulating member and another part of the first insulating member in the first direction,
a second electrode portion position of the second electrode portion in the first direction being between a first electrode portion position of the first electrode portion in the first direction and a second electrode portion position of the second electrode in the first direction,
the second electrode portion not overlapping the first insulating member in the first direction,
the first conductive member includes a first conductive portion,
a first conductive portion position of the first conductive portion in the first direction being between a second conductive member position of the second conductive member in the first direction and the second electrode position,
at least a part of the first conductive portion overlapping the second conductive member in the first direction,
at least a part of the second conductive member overlapping the third electrode in the second direction,
the first conductive portion including a first portion and a second portion,
the first portion overlapping the second electrode portion in the second direction,
the second portion not overlapping the third electrode portion in the second direction,
a first length of the first conductive portion along the first direction being longer than a second length of the second electrode portion along the first direction.

3. The semiconductor device according to claim 2, wherein
at least a part of the first electrode portion is provided between the first semiconductor portion and the second semiconductor portion in the first direction.

4. The semiconductor device according to claim 2, wherein
a part of the first electrode portion is provided between the fourth partial region and the fifth partial region in the first direction.

5. The semiconductor device according to claim 4, further comprising:
a first compound member including Al_{z1}Ga_{1-z1}N (0<z1≤1),
the first compound member being provided between the semiconductor member and the first insulating member.

6. The semiconductor device according to claim 2, further comprising:
a fourth insulating member,
the fourth insulating member including a first insulating region and a second insulating region,
the first semiconductor portion being between the fourth partial region and the first insulating region in the second direction, and
the second semiconductor portion being between the fifth partial region and the second insulating region in the second direction.

7. The semiconductor device according to claim 1, wherein
The first conductive portion is spaced from the second conductive member in the first direction.

8. The semiconductor device according to claim 1, wherein
a first distance along the first direction between the first electrode and the third electrode is shorter than a second distance along the first direction between the third electrode and the second electrode.

9. The semiconductor device according to claim 8, wherein
a third length of the second portion along the first direction is not less than 0.05 times and not more than 0.7 times the second distance.

10. The semiconductor device according to claim 1, further comprising:
a second conductive member connecting portion,
the second conductive member connecting portion is between the third electrode and the second conductive member in the second direction,
the second conductive member connecting portion electrically connects the second conductive member to the third electrode, and
a width of the second conductive member connecting portion in the first direction is shorter than the second length and shorter than a fourth length of the second conductive member in the first direction.

11. The semiconductor device according to claim 1, further comprising:
a first conductive member connecting portion,
the first conductive member connecting portion electrically connects the first conductive member to the first electrode.

12. The semiconductor device according to claim 1, wherein
the first conductive member further includes a second conductive portion,
the second conductive portion is continuous with the first conductive portion, and
at least a part of the second conductive member is between the third electrode and the second conductive portion in the second direction.

13. The semiconductor device according to claim 1, wherein
the first conductive member further includes a second conductive portion,
the second conductive portion is continuous with the first conductive portion,
a second conductive portion position of the second conductive portion in the first direction is between a first portion position of the first portion in the first direction and the second electrode position, and
at least a part of the second portion is between the semiconductor member and the second conductive portion in the second direction.

14. The semiconductor device according to claim 1, wherein
the first portion is provided between the third electrode and a part of the second conductive member in the second direction.

15. The semiconductor device according to claim 1, wherein
the second semiconductor region further includes a third semiconductor portion, and
the third semiconductor portion is between the third partial region and the third electrode in the second direction.

16. The semiconductor device according to claim 1, wherein
a part of the first insulating member is provided between the semiconductor member and a part of the second electrode.

17. The semiconductor device according to claim 1, further comprising:
a second insulating member, and
at least a part of the second insulating member being provided between the third electrode and the first conductive portion.

18. The semiconductor device according to claim 1, further comprising:
a third insulating member, and
at least a part of the third insulating member being provided between the second conductive member and the first conductive portion in the first direction.

19. The semiconductor device according to claim 1, wherein
no other conductive member electrically connected to the first electrode and separated from the first conductive member is provided between the first conductive member and the second electrode.

20. The semiconductor device according to claim 1, further comprising:
a third conductive member electrically connected to the first electrode, and
the first conductive member is provided between the semiconductor member and at least a part of the third conductive member in the second direction.
